(19) United States
(12) Patent Application Publication
(10) Pub. No.: US 2024/0337765 A1
(43) Pub. Date: Oct. 10, 2024

(54) SILICON DRIFT DETECTION ELEMENT, SILICON DRIFT DETECTOR, AND RADIATION DETECTION DEVICE

(71) Applicant: HORIBA, LTD., Kyoto-shi (JP)

(72) Inventors: Daisuke MATSUNAGA, Kyoto (JP); Junichi AOYAMA, Kyoto (JP); Yuji OKUBO, Kyoto (JP); Seiji IKAWA, Kyoto (JP)

(21) Appl. No.: 18/744,506

(22) Filed: Jun. 14, 2024

Related U.S. Application Data
(62) Division of application No. 16/765,325, filed on May 19, 2020.

(30) Foreign Application Priority Data
Dec. 15, 2017 (JP) 2017-240836

(51) Int. Cl. G01T 1/24; G01N 23/223; H01L 31/0203; H01L 31/0216; H01L 31/0224; H01L 31/08

(52) U.S. Cl. CPC G01T 1/247; G01T 1/241; H01L 31/0203; H01L 31/02164; H01L 31/0224; H01L 31/085; G01N 23/223

(57) ABSTRACT

A silicon drift detector includes a housing and a silicon drift detection element that is disposed inside the housing. The housing includes an opening that is not closed. The silicon drift detection element includes a top surface facing the opening, and a light shielding film is provided on the top surface.

### CROSS-REFERENCE TO RELATED APPLICATIONS

This application is a divisional of U.S. application Ser. No. 16/765,325 filed on May 19, 2020, which is a 371 of PCT/JP2018/046005 filed on Dec. 14, 2018 which, in turn, claimed the priority of Japanese Patent Application No. 2017-240836 filed on Dec. 15, 2017, and the above applications are incorporated herein by reference.

### FIELD

The present invention relates to a silicon drift detection element, a silicon drift detector, and a radiation detection device.

### BACKGROUND

A radiation detector which detects a radiation such as an X-ray may include a radiation detection element using a semiconductor. The radiation detection element using a semiconductor may be, for example, a silicon drift detection element. The radiation detector including the silicon drift detection element is a silicon drift detector (SDD).

In the related art, such a radiation detection element is cooled and used so as to reduce noise. The radiation detector includes a housing, the radiation detection element, and a cooling unit such as a Peltier element. The radiation detection element and the cooling unit are disposed inside the housing. In order to prevent condensation caused by cooling, the housing is in an airtight state, and the inside of the housing is depressurized or is filled with a dry gas. In addition, the radiation detection element is isolated from the housing as thermally as possible.

The housing is provided with a window including a window plate made of a material that transmits a radiation. The radiation which is transmitted through the window plate is incident into the radiation detection element, so that the radiation is detected. The window plate serves to perform light shielding such that light is prevented from being incident into the radiation detection element. In addition, the window plate is required to have a structural strength to maintain the airtight state. Japanese Patent Laid-Open Publication No. 2000-55839 discloses an example of the radiation detector.

### SUMMARY

The radiation detection element may be brought close to a sample so as to improve the efficiency of detecting a radiation generated from the sample. However, in the radiation detector of the related art, the housing and the window plate are required to have certain sizes to maintain the airtight state of the housing, and the entire size of the radiation detector increases. Due to the entire size of the radiation detector, there is a lower limit to a distance within which the radiation detection element can be brought close to the sample, and there is a limit to improving a detection efficiency.

In addition, the window plate is required to have a certain thickness to maintain the airtight state. Due to the thickness of the window plate, the transmissivity where a low-energy radiation is transmitted through the window plate is low, and it is difficult for the low-energy radiation to be incident into the radiation detection element. For this reason, such a radiation detector has a low sensitivity for detecting the low-energy radiation.

The present disclosure has been made in light of such circumstances, and it is an object to provide a silicon drift detection element, a silicon drift detector, and a radiation detection device in which the efficiency of detecting a radiation and the sensitivity of detecting a low-energy radiation are improved.

In a silicon drift detection element according to an aspect of the present disclosure, a light shielding film is provided on a top surface of the silicon drift detection element, a radiation being incident into the top surface.

In an aspect of the present disclosure, the light shielding film is provided on the top surface of the silicon drift detection element into which the radiation is incident. The light shielding film prevents the occurrence of noise which is due to light, and the silicon drift detection element is operable.

In the silicon drift detection element according to an aspect of the present disclosure, the light shielding film reduces an amount of light incident into the top surface to less than 0.1%.

In an aspect of the present disclosure, since the light shielding film reduces the amount of light to less than 0.1%, the occurrence of noise is effectively prevented.

In the silicon drift detection element according to an aspect of the present disclosure, the light shielding film is a metallic film with a thickness exceeding 50 nm but less than 500 nm.

In an aspect of the present disclosure, since the metallic film with a thickness exceeding 50 nm but less than 500 nm is used as the light shielding film, sufficient enough light shielding properties are obtained.

In the silicon drift detection element according to an aspect of the present disclosure, the light shielding film is a carbon film.

In an aspect of the present disclosure, since the carbon film is used as the light shielding film, light shielding properties are obtained.

The silicon drift detection element according to an aspect of the present disclosure further comprises: a signal output electrode which is provided in a back surface opposite to the top surface, into which an electric charge generated by an incidence of the radiation flows and which outputs a signal depending on the electric charge; a first electrode which is provided in the top surface and to which a voltage is applied; and a plurality of second electrodes that are provided in the back surface to surround the signal output electrode, and are positioned at different distances from the signal output electrode, The second electrode has a shape where a length of the second electrode in one direction along the back surface is longer than a length thereof in the other direction along the back surface, and the signal output electrode includes a plurality of electrodes that are arranged in the one direction and are connected to each other.

In one aspect of the present disclosure, the silicon drift detection element includes the signal output electrode provided in the back surface, the first electrode provided in the top surface, and the plurality of second electrodes that are provided in the back surface to surround the signal output electrode. A voltage is applied to the second electrodes to generate a potential gradient where the potential changes toward the signal output electrode. The second electrode has a shape where the length of the second electrode in the one direction is longer than the length thereof in the other direction, and the signal output electrode includes a plurality of electrodes that are arranged along the one direction. The plurality of electrodes are connected to each other. An increase in the area of the signal output electrode is suppressed, a change in the distance between the signal output electrode and the second electrode is small, and a variation in the speed where electric charges are collected toward the signal output electrode is small.

The silicon drift detection element according to an aspect of the present disclosure further comprises: a signal output electrode which is provided in a back surface opposite to the top surface, into which an electric charge generated by an incidence of the radiation flows and which outputs a signal depending on the electric charge; a first electrode which is provided in the top surface and to which a voltage is applied; and a plurality of second electrodes that are provided in the back surface to surround the signal output electrode, and are positioned at different distances from the signal output electrode. The second electrode has a shape where a length of the second electrode in one direction along the back surface is longer than a length thereof in the other direction along the back surface, and the signal output electrode includes a line electrode that is provided in the back surface to extend along the one direction.

In one aspect of the present disclosure, the second electrode has a shape where the length of the second electrode in the one direction is longer than the length thereof in the other direction, and the signal output electrode includes a line electrode that extends along the one direction. An increase in the area of the signal output electrode is suppressed, a change in the distance between the signal output electrode including the line electrode and the second electrode is small, and a variation in the speed where electric charges are collected toward the signal output electrode is small.

A silicon drift detector according to an aspect of the present disclosure comprises: a housing; and the silicon drift detection element according to an aspect of the present disclosure which is disposed inside the housing. The housing includes an opening that is not closed, the silicon drift detection element includes a top surface facing the opening, and a light shielding film is provided on the top surface.

In an aspect of the present disclosure, the housing of the silicon drift detector includes the opening, and a light shielding film is provided on a top surface of the silicon drift detection element into which a radiation is incident. The light shielding film prevents the occurrence of noise which is due to light, and the silicon drift detection element is operable. For this reason, a window including a window plate for light shielding is not required to be provided in the opening, and the opening is not closed. Since the silicon drift detector does not include the window, even a low-energy radiation is easily incident into the silicon drift detection element. In addition, the size of the silicon drift detector becomes small.

In the silicon drift detector according to an aspect of the present disclosure, the top surface is larger than the opening, the housing includes an overlapping portion that includes an edge of the opening and overlaps a part of the top surface, and a portion in the top surface, which is surrounded by another portion overlapped with the overlapping portion, is covered with the light shielding film.

In an aspect of the present disclosure, a part of the housing overlaps a part of the top surface of the silicon drift detection element, and a portion in the top surface, which is surrounded by another portion overlapped with the housing, is covered with the light shielding film. A portion of the silicon drift detection element into which the radiation is incident is shielded from light, and the occurrence of noise due to the light is prevented. The silicon drift detector can be used in an environment where visible light is incident into the silicon drift detector.

In the silicon drift detector according to an aspect of the present disclosure, the silicon drift detector does not include a cooling unit that cools the silicon drift detection element, and the housing is not airtight.

In an aspect of the present disclosure, the silicon drift detector does not include the cooling unit such as a Peltier element that cools the silicon drift detection element. In recent years, owing to a noise reduction in electric circuits and the like, the silicon drift detector can have sufficient performance even when cooling is not performed. Since the cooling is not performed, the housing is not required to be airtight. For this reason, it is possible to decrease the size of the housing, and the size of the silicon drift detector becomes small.

In the silicon drift detector according to an aspect of the present disclosure, a window plate is not provided at a position facing the top surface.

In an aspect of the present disclosure, the window plate is not provided at the position facing the top surface of the silicon drift detection element into which the radiation is incident. Since no radiation is transmitted through the window plate, even a low-energy radiation is more easily incident into the silicon drift detection element. In addition, the size of the silicon drift detector becomes small.

The silicon drift detector according to an aspect of the present disclosure further comprises a filler with which a gap between the housing and the silicon drift detection element is filled.

In one aspect of the present disclosure, the gap between the housing and the silicon drift detection element is filled with the filler such as a resin. A bonding wire connected to the silicon drift detection element is embedded in the filler, so that the bonding wire is protected from moisture.

A radiation detection device according to an aspect of the present disclosure comprises: the silicon drift detector according to an aspect of the present disclosure; and a spectrum generation unit that generates a spectrum of a radiation detected by the silicon drift detector.

A radiation detection device according to an aspect of the present disclosure comprises: an irradiation unit that irradiates a sample with a radiation; the silicon drift detector according to an aspect of the present disclosure, which detects a radiation generated from the sample; a spectrum generation unit that generates a spectrum of the radiation detected by the silicon drift detector; and a display unit that displays the spectrum generated by the spectrum generation unit.

In an aspect of the present disclosure, since the size of the silicon drift detector is small, in the radiation detection device, the silicon drift detector can be brought close to a sample. Since the silicon drift detector is brought close to the sample, the efficiency of detecting a radiation generated from the sample is improved. In addition, even a low-energy radiation is more easily incident into the silicon drift detection element, so that the sensitivity of detecting the low-energy radiation is improved. For this reason, the radiation detection device facilitates the analysis of light elements.

In an aspect of the present disclosure, since even a low-energy radiation is easily incident into the silicon drift detection element, the sensitivity of detecting the low-energy radiation is improved. In addition, since the silicon drift detector is brought close to the sample, an aspect of the present disclosure has good effects such as improving the efficiency of detecting a radiation generated from the sample.

The above and further objects and features will more fully be apparent from the following detailed description with accompanying drawings.

### BRIEF DESCRIPTION OF THE DRAWINGS

FIG. 1 is a schematic cross-sectional view illustrating an example of configuration of a radiation detector according to a first embodiment;

FIG. 2 is a block diagram illustrating the configuration of a radiation detection device according to the first embodiment;

FIG. 3 is a schematic cross-sectional view illustrating a radiation detection element and a part of a cover according to the first embodiment;

FIG. 4 is a schematic cross-sectional view illustrating one example of a light shielding film;

FIG. 5 is a schematic cross-sectional view illustrating another example of the light shielding film;

FIG. 6 is a schematic cross-sectional view illustrating another example of configuration of the radiation detector according to the first embodiment;

FIG. 7 is a schematic cross-sectional view illustrating an example of configuration of a radiation detector according to a second embodiment;

FIG. 8 is a schematic plan view of a radiation detection element according to a third embodiment;

FIG. 9 is a schematic plan view illustrating a second example of configuration of a signal output electrode in the third embodiment;

FIG. 10 is a schematic plan view illustrating a third example of configuration of the signal output electrode in the third embodiment;

FIG. 11 is a block diagram illustrating the configuration of a radiation detection device according to a fourth embodiment;

FIG. 12 is a schematic view illustrating an example of configuration of the inside of a radiation detector according to the fourth embodiment;

FIG. 13 is a schematic perspective view illustrating an example of the disposition of a plurality of the radiation detectors according to the fourth embodiment; and

FIG. 14 is a schematic view illustrating an example of the disposition of an irradiation unit, the radiation detectors, and a sample according to the fourth embodiment.

### DETAILED DESCRIPTION

Hereinafter, the present disclosure will be specifically described based on the drawings illustrating embodiments thereof.

### First Embodiment

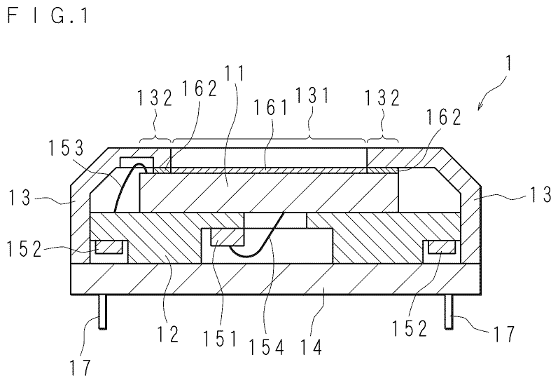

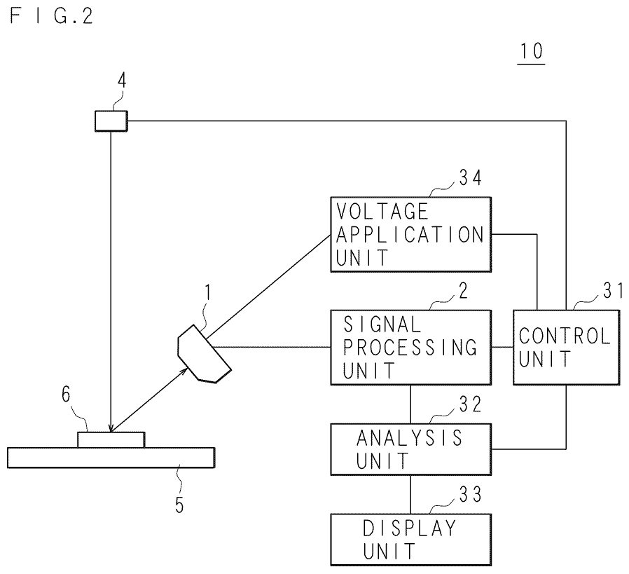

FIG. 1 is a schematic cross-sectional view illustrating an example of configuration of a radiation detector 1 according to a first embodiment. FIG. 2 is a block diagram illustrating the configuration of a radiation detection device 10 according to the first embodiment. The radiation detection device 10 is, for example, an X-ray fluorescence spectrometer. The radiation detection device 10 includes an irradiation unit 4 that irradiates a sample 6 with a radiation such as an electron beam or an X-ray, a sample stage 5 on which the sample 6 is placed, and the radiation detector 1. The sample 6 is irradiated with the radiation from the irradiation unit 4, so that a radiation such as a fluorescent X-ray is generated from the sample 6, and the radiation detector 1 detects the radiation generated from the sample 6. In the drawing, the radiation is indicated by the arrows. The radiation detector 1 outputs a signal proportional to the energy of the detected radiation. It is noted that the radiation detection device 10 may be configured to hold the sample 6 in a method other than the method for placing the sample 6 on the sample stage 5.

The radiation detector 1 is connected to a signal processing unit 2 that processes the output signal, and a voltage application unit 34 that applies a voltage required for radiation detection to a radiation detection element 11 which is included in the radiation detector 1. The signal processing unit 2 performs a process of counting a signal with each value output from the radiation detector 1, and generating a relationship between the energy of radiation and a count number, namely, a spectrum of the radiation. The signal processing unit 2 corresponds to a spectrum generation unit.

The signal processing unit 2 is connected to an analysis unit 32. The analysis unit 32 is configured to include a calculation unit that performs a calculation, and a memory that stores data. The signal processing unit 2, the analysis unit 32, the voltage application unit 34, and the irradiation unit 4 are connected to a control unit 31. The control unit 31 controls operations of the signal processing unit 2, the analysis unit 32, the voltage application unit 34, and the irradiation unit 4. The signal processing unit 2 outputs data, which indicates the generated spectrum, to the analysis unit 32. The analysis unit 32 receives the data from the signal processing unit 2 to perform a qualitative analysis or a quantitative analysis of elements contained in the sample 6 based on the spectrum indicating the input data. A display unit 33 such as a liquid crystal display is connected to the analysis unit 32. The display unit 33 displays an analysis result obtained by the analysis unit 32. In addition, the display unit 33 displays the spectrum generated by the signal processing unit 2. The control unit 31 may be configured to receive an operation of a user to control each part of the radiation detection device 10 according to the received operation. In addition, the control unit 31 and the analysis unit 32 may be configured as the same computer.

As illustrated in FIG. 1, the radiation detector 1 includes a bottom plate portion 14 having a plate shape. A cover 13 having a cap shape covers one surface side of the bottom plate portion 14. The cover 13 has a shape where a truncated cone is connected to one end of a cylinder, and the other end of the cylinder is joined to the bottom plate portion 14. An opening 131 is formed in a truncated portion at a tip of the cover 13. A window including a window plate is not provided in the opening 131, and the opening 131 is not closed. The cover 13 and the bottom plate portion 14 form a housing of the radiation detector 1. The inside of the cover 13 and the bottom plate portion 14 is not airtight. Here, an airtight state is a state where no gas exchange between the inside and outside of the cover 13 and the bottom plate portion 14. In other words, in this embodiment, there is an exchange of gas between inside and outside of the cover 13 and the bottom plate portion 14. The access of gas between inside and outside of the cover 13 and the bottom plate portion 14 through the opening 131 or a portion other than the opening 131 is allowed.

The radiation detection element 11 and a substrate 12 are disposed inside the cover 13. The substrate 12 includes a surface facing the opening 131, and the radiation detection element 11 is disposed on the surface. There may be an interposed object between the substrate 12 and the radiation detection element 11. It is desirable that the substrate 12 is made of a material which generates as little radiation as possible upon irradiation with radiation. The material of the substrate 12 is, for example, ceramic. The radiation detection element 11 is a silicon drift detection element, and the radiation detector 1 is a silicon drift detector. The radiation detection element 11 has, for example, a plate shape. The radiation detection element 11 is disposed at a position facing the opening 131. In recent years, owing to a noise reduction in electric circuits and the like, the radiation detector can have sufficient performance even when cooling is not performed. For this reason, the radiation detection element 11 is operable without being cooled. In other words, the radiation detection element 11 is operable at a room temperature. The radiation detector 1 does not include a cooling unit such as a Peltier element that cools the radiation detection element 11.

A wiring is provided on the substrate 12. The wiring on the substrate 12 and the radiation detection element 11 are electrically connected to each other via a bonding wire 153. A recess which is recessed from an inner surface of the cover 13 is formed in the cover 13 to allow the bonding wire 153 to pass therein. Since the recess is provided, an increase in the entire size of the radiation detector 1 by which the bonding wire 153 is allowed to pass is prevented. The wiring on the substrate 12 and the radiation detection element 11 may be, as will be described later, connected to each other in a method other than the method where the bonding wire 153 is connected to the radiation detection element 11. An amplifier 151 and various components 152 required for the operation of the radiation detector 1 are provided on a surface of the substrate 12 which is opposite to the surface facing the opening 131. The components 152 include, for example, an electro-static discharge (ESD) protection component. The ESD protection component is, for example, a capacitor, a diode, or a varistor. The radiation detector 1 is more easily influenced from outside than the configuration where the opening is closed. Since the radiation detector 1 includes the ESD protection component, the ESD protection can be enhanced so as to restrain an adverse influence caused by ESD.

A through-hole is provided in the substrate 12. The amplifier 151 is connected to the radiation detection element 11 via a bonding wire 154 that is disposed to pass through the through-hole. The amplifier 151 and the components 152 are electrically connected to the wiring on the substrate 12. It is noted that the shape of the substrate 12 illustrated in FIG. 1 is one example. The substrate 12 may not include the through-hole, and the amplifier 151 may be connected to the radiation detection element 11 in a method other than the method where the bonding wire 154 passing through the through-hole is used.

In addition, the radiation detector 1 includes a plurality of lead pins 17. The lead pins 17 pass through the bottom plate portion 14. The wiring on the substrate 12 and the lead pins 17 are electrically connected to each other. By using the lead pins 17, a voltage is applied to the radiation detection element 11 and a signal is input to and output from the radiation detection element 11.

The amplifier 151 is, for example, a preamplifier. The radiation detection element 11 outputs a signal proportional to the energy of the detected radiation, and the output signal is input to the amplifier 151 through the bonding wire 154. The amplifier 151 performs the conversion and amplification of the signal. The signal after conversion and amplification is output from the amplifier 151, and is output outside the radiation detector 1 through the lead pins 17. In such a manner, the radiation detector 1 outputs the signal proportional to the energy of the radiation detected by the radiation detection element 11. The output signal is output to the signal processing unit 2. It is noted that the amplifier 151 may also have a function other than the function of the preamplifier. In addition, the amplifier 151 may be disposed outside the radiation detector 1.

The signal processing unit 2 may have a function of correcting an influence of temperature on the signal from the amplifier 151. The intensity of the signal output from the radiation detection element 11 is influenced by temperature. A leakage current which does not originate from the radiation occurs in the radiation detection element 11, and the signal from the amplifier 151 contains a signal corresponding to the leakage current. The leakage current is influenced by temperature. The signal processing unit 2 may determine the degree of an influence of temperature on the signal based on the signal corresponding to the leakage current, and may perform a process of correcting the influence of temperature on the signal from the amplifier 151 according to the determined degree. In addition, the radiation detector 1 may include a temperature measurement unit such as a thermistor that measures a temperature inside the radiation detector 1. The signal processing unit 2 may perform the process of correcting an influence of temperature on the signal from the amplifier 151 according to a result of measurement of the temperature by the temperature measurement unit. In addition, the analysis unit 32 may perform the process of correcting an influence of temperature on the signal.

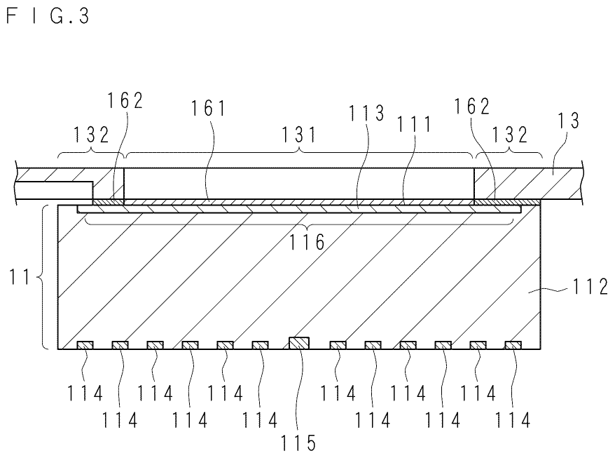

FIG. 3 is a schematic cross-sectional view illustrating the radiation detection element 11 and a part of the cover 13 according to the first embodiment. The radiation detection element 11 includes a top surface 111 facing the opening 131. The radiation detection element 11 includes a light shielding film 161 covering a part of the top surface 111. The top surface 111 is larger than the opening 131. A portion of the cover 13 overlaps a part of the top surface 111 when viewed in a direction orthogonal to the top surface 111 from a viewpoint facing the top surface 111 of the radiation detection element 11. The portion of the cover 13 which overlaps the part of the top surface 111 is referred to as an overlapping portion 132. The overlapping portion 132 includes an edge of the opening 131. The overlapping portion 132 is bonded to the top surface 111 of the radiation detection element 11 with a bonding member 162 interposed therebetween.

The radiation detection element 11 includes a semiconductor portion 112 having a plate shape. The component of the semiconductor portion 112 is, for example, n-type silicon. A first electrode 113 is provided in the top surface 111. The first electrode 113 is continuously provided in a region including a central portion of the top surface 111. The first electrode 113 is provided up to the vicinity of a peripheral edge of the top surface 111, and occupies the majority of the top surface 111. The first electrode 113 is connected to the voltage application unit 34. Multiplexed second electrodes 114 having a loop shape are provided in a back surface of the radiation detection element 11 which is opposite to the top surface 111. A signal output electrode 115, which is an electrode that outputs a signal when a radiation is detected, is provided at a position that is surrounded by the multiplexed second electrodes 114. The signal output electrode 115 is connected to the amplifier 151. Among the multiplexed second electrodes 114, the second electrode 114 which is closest to the signal output electrode 115 and the second electrode 114 which is farthest from the signal output electrode 115 are connected to the voltage application unit 34.

The voltage application unit 34 applies a voltage to the multiplexed second electrodes 114 such that the potential of the second electrode 114 which is closest to the signal output electrode 115 is highest and the potential of the second electrode 114 which is farthest from the signal output electrode 115 is lowest. In addition, the radiation detection element 11 is configured to generate a predetermined electrical resistance between the second electrodes 114 adjacent to each other. For example, since the chemical composition of a portion of the semiconductor portion 112 which is positioned between the second electrodes 114 adjacent to each other is adjusted, an electrical resistance channel connected to the two second electrodes 114 is formed. In other words, the multiplexed second electrodes 114 are connected to each other in a daisy chain pattern via electrical resistances. When a voltage is applied from the voltage application unit 34 to the multiplexed second electrodes 114, the second electrodes 114 have potentials that increase sequentially and monotonically from the second electrode 114 which is far from the signal output electrode 115 toward the second electrode 114 which is close to the signal output electrode 115. It is noted that a plurality of the second electrodes 114 may include a pair of the second electrodes 114 adjacent to each other which have the same potential.

Due to the potentials of the plurality of second electrodes 114, an electric field where the closer to the signal output electrode 115, the higher the potential, and the farther from the signal output electrode 115, the lower the potential is generated in a stepwise manner inside the semiconductor portion 112. Furthermore, the voltage application unit 34 applies a voltage to the first electrode 113 such that the potential of the first electrode 113 is lower than that of the second electrode 114 with the highest potential. In such a manner, a voltage is applied to the semiconductor portion 112 between the first electrode 113 and the second electrodes 114, and thus, an electric field where the closer to the signal output electrode 115, the higher the potential is generated inside the semiconductor portion 112.

The radiation detector 1 is disposed such that the opening 131 faces a placement surface of the sample stage 5. In other words, in a state where the sample 6 is placed on the sample stage 5, the top surface 111 of the radiation detection element 11 faces the sample 6. A radiation from the sample 6 is transmitted through the first electrode 113, and is incident into the semiconductor portion 112 from the top surface 111. The radiation is absorbed by the semiconductor portion 112, and an amount of electric charges are generated according to the energy of the absorbed radiation. The generated electric charges are electrons and positive holes. The generated electric charges move due to the electric field inside the semiconductor portion 112, and one type of electric charges flow into the signal output electrode 115. In this embodiment, when the signal output electrode 115 is an n type, electrons generated by the incidence of the radiation move to flow into the signal output electrode 115. The electric charges which have flown into the signal output electrode 115 are output as a current signal, and the current signal is input into the amplifier 151.

As illustrated in FIG. 3, the first electrode 113 is not provided in a peripheral edge portion of the top surface 111 of the radiation detection element 11. In the semiconductor portion 112, a portion capable of detecting the incident radiation is a portion where an electric field is generated to cause electric charges to flow toward the signal output electrode 115 when a voltage is applied to the first electrode 113 and the second electrode 114. In the top surface 111, a region on a top surface of the portion of the semiconductor portion 112 which is capable of detecting the radiation is referred to as a sensitive region 116. A radiation incident into the sensitive region 116 can be detected by the radiation detection element 11. In a portion of the semiconductor portion 112, of which the top surface is a region other than the sensitive region 116, an electric field to cause electric charges to flow toward the signal output electrode 115 is not generated or the intensity of an electric field to cause electric charges to flow toward the signal output electrode 115 is weak, and thus, the incident radiation is difficult to detect. For example, the sensitive region 116 is a region including the central portion of the top surface 111, and the edge of the top surface 111 is not included in the sensitive region 116.

The overlapping portion 132 of the cover 13 overlaps a region including the edge of the top surface 111. The portion in the top surface 111, which is surrounded by another portion overlapped with the overlapping portion 132, is not overlapped with the overlapping portion 132 and is included in the sensitive region 116. For example, the overlapping portion 132 overlaps the region other than the sensitive region 116, and a part of the sensitive region 116. For another example, the overlapping portion 132 overlaps the region which is not the sensitive region 116, and the sensitive region 116 faces the opening 131. The overlapping portion 132 is made of a material that has light shielding properties and shields a radiation. The overlapping portion 132 is made of, for example, a metal-containing material. More specifically, the overlapping portion 132 is made of a metal or a resin that is mixed with a metal having a larger atomic number than zinc such as barium. Since the overlapping portion 132 is made of a metal-containing material, the radiation is effectively shielded. The overlapping portion 132 shields a part of the radiation incident into the radiation detector 1, and a radiation which is not shielded by the overlapping portion 132 to pass through the opening 131 is incident into the sensitive region 116 and is detected by the radiation detection element 11.

Consequently, the overlapping portion 132 serves as a collimator that limits a radiation incidence range. For this reason, the radiation detector 1 does not require the collimator without a deterioration in radiation detection performance as compared to that in the related art. In other words, the radiation detector 1 does not include the collimator. Since the collimator is not disposed inside the cover 13, the size of the cover 13 is smaller than that of a cover of a radiation detector with the collimator in the related art, and the size of the radiation detector 1 is smaller than that of the radiation detector.

The bonding member 162 has light shielding properties. Since the bonding member 162 has light shielding properties, light is prevented from being incident into the cover 13 and then being into the radiation detection element 11, and the occurrence of noise due to light is prevented. In a case where the light shielding film 161 fills a gap between the cover 13 and the radiation detection element 11, the light shielding film 161 can shield the gap between the cover 13 and the radiation detection element 11 from light. However, when the bonding member 162 is thicker than the light shielding film 161, the light shielding film 161 cannot fill the gap between the cover 13 and the radiation detection element 11, and thus, the bonding member 162 is required to have light shielding properties. In many cases, since the bonding member 162 is thicker than the light shielding film 161, it is desirable that the bonding member 162 has light shielding properties. It is desirable that the bonding member 162 reduces the amount of light to less than 0.1%. When the amount of light is reduced to less than 0.1%, the occurrence of noise is effectively prevented. Light may be reduced to zero.

When overlapping portion 132 has conductivity such as when the overlapping portion 132 is made of a metal-containing material, the bonding member 162 has insulation properties. Since the bonding member 162 has insulation properties, electrical contact between the overlapping portion 132 and the radiation detection element 11 is prevented, and a voltage is prevented from being applied to the cover 13. Therefore, a voltage applied to the radiation detection element 11 is prevented from being unstable, and a deterioration in the performance of the radiation detector 1 is prevented. It is desirable that the bonding member 162 is provided over the entirety of the peripheral edge portion of the top surface 111. When the bonding member 162 is provided over the entirety of the peripheral edge portion of the top surface 111, light is not allowed to enter inside the cover 13. In addition, when the radiation detector 1 is assembled, the positioning of the radiation detection element 11 with respect to the cover 13 can be easily performed. It is noted that another component such as a protective film may be interposed between the top surface 111 of the radiation detection element 11 and the bonding member 162.

The bonding member 162 may not have insulation properties. When the overlapping portion 132 has no conductivity, the bonding member 162 may not have insulation properties. In addition, when the bonding member 162 has no insulation properties and the overlapping portion 132 has conductivity, the radiation detector 1 may be configured such that the radiation detection element 11 and the wiring on the substrate 12 are connected to each other via the overlapping portion 132. For example, the radiation detection element 11 and the overlapping portion 132 are electrically connected to each other, and the overlapping portion 132 and the wiring on the substrate 12 are connected to each other via a bonding wire. In such a manner, the radiation detection element 11 and the wiring on the substrate 12 are connected to each other in a method other than the method where the bonding wire 153 is connected to the radiation detection element 11. A voltage is applied to the overlapping portion 132 through the wiring on the substrate 12, and the voltage is applied to the radiation detection element 11 through the overlapping portion 132. In this case, the overlapping portion 132 is required to be insulated from the bottom plate portion 14, the lead pins 17, and the substrate 12.

In the top surface 111 of the radiation detection element 11, the portion which is surrounded by another portion overlapped with the overlapping portion 132 is covered with the light shielding film 161. A position which faces the light shielding film 161 on the top surface 111 is open by the opening 131. The radiation detector 1 is used in a state where the light shielding film 161 is in vacuum or also in a state where the light shielding film 161 is exposed to an atmospheric air. Due to the light shielding film 161, light is prevented from being incident into the top surface 111, and noise due to light is prevented from occurring in the radiation detection element 11. Particularly, the light shielding film 161 prevents light from causing noise in a portion of the radiation detection element 11 into which a radiation is incident. It is desirable that the light shielding film 161 reduces the amount of light to less than 0.1%. When the amount of light incident into the top surface 111 is reduced to less than 0.1%, noise occurring in the radiation detection element 11 is sufficiently reduced. Since the light shielding film 161 shields light incident into the radiation detection element 11, the radiation detector 1 can be used in an environment where visible light is incident into the radiation detector 1.

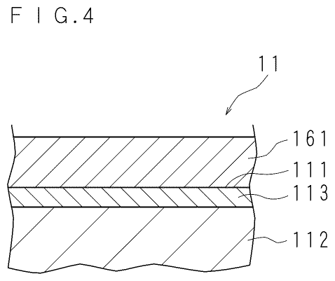

FIG. 4 is a schematic cross-sectional view illustrating one example of the light shielding film 161. The light shielding film 161 which is a metallic film is provided on the top surface 111 of the radiation detection element 11. The light shielding film 161 which is a metallic film has light shielding properties. The component of the light shielding film 161 which is a metallic film is, for example, aluminum (Al), gold (Au), a lithium alloy, beryllium, or magnesium. When the light shielding film 161 is made of Al, it is desirable that the thickness of the light shielding film 161 exceeds 50 nm but is less than 500 nm. When the thickness of the light shielding film 161 made of Al exceeds 50 nm, light shielding properties required to reduce noise in the radiation detection element 11 are obtained. When the thickness of the light shielding film 161 is 500 nm or greater, the sensitivity for a low-energy X-ray decreases. More preferably, the thickness of the light shielding film 161 made of Al is from 100 nm to 350 nm. An oxide film may be provided between the light shielding film 161 and the first electrode 113. In addition, a protective film which protects the light shielding film 161 may be provided on a top surface of the light shielding film 161. For example, the component of the protective film may be aluminum oxide (Al₂O₃) or silicon dioxide (SiO₂).

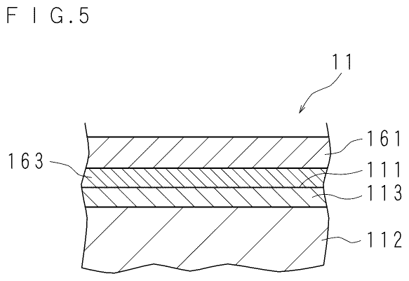

FIG. 5 is a schematic cross-sectional view illustrating another example of the light shielding film 161. A metallic film 163 is provided on the top surface 111 of the radiation detection element 11, and the light shielding film 161 which is a carbon film is provided on the metallic film 163. The component of the metallic film 163 is, for example, Al or Au. The component of the light shielding film 161 which is a carbon film is, for example, graphene carbon. Even when the light shielding film 161 is a carbon film, light shielding is effectively performed. The carbon film is good in chemical resistance and corrosion resistance. It is difficult for visible light to pass through the carbon film, whereas the X-ray is easily transmitted through the carbon film. In addition, it is more difficult for a characteristic X-ray to be generated in the carbon film when the carbon film is irradiated with a radiation than in the metallic film. For this reason, it is difficult for a so-called system peak to occur when the radiation is detected, and the accuracy of detecting the radiation is further improved. A protective film which protects the light shielding film 161 may be provided on the top surface of the light shielding film 161 overlapping the metallic film 163. For example, the component of the protective film is Al₂O₃ or SiO₂. In addition, the radiation detector 1 may not include the metallic film 163, and the light shielding film 161 which is a carbon film may be provided directly on the top surface 111 of the radiation detection element 11. In addition, an oxide film may be provided between the top surface 111 of the radiation detection element 11 and the metallic film 163 or the light shielding film 161 which is a carbon film.

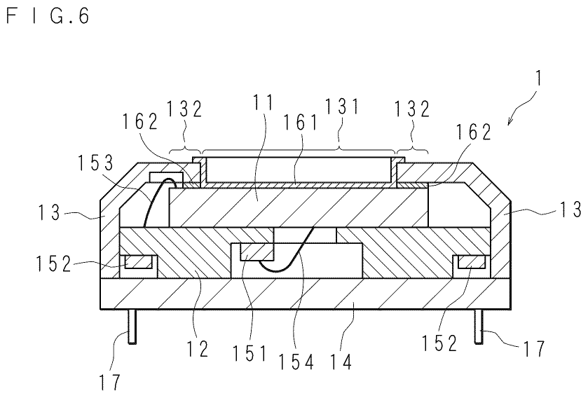

The light shielding film 161 may not be provided in a part of the radiation detection element 11. FIG. 6 is a schematic cross-sectional view illustrating another example of configuration of the radiation detector 1 according to the first embodiment. The portion, in the top surface 111 of the radiation detection element 11, which is surrounded by another portion overlapped with the overlapping portion 132, an end surface of the overlapping portion 132, and a part of the overlapping portion 132 are covered with the light shielding film 161. The configuration of the radiation detector 1 except the light shielding film 161 is the same as that in the example illustrated in FIG. 1. For example, the light shielding film 161 is formed in a final step when the radiation detector 1 is assembled, so that the example illustrated in FIG. 6 is configured. In this example, the light shielding film 161 is a configuration portion of the radiation detector 1, which is separate from the radiation detection element 11. Also in this example, the position which faces the light shielding film 161 on the top surface 111 is open.

In the first embodiment, since the portion, in the top surface 111 of the radiation detection element 11, which is surrounded by another portion overlapped with the overlapping portion of the cover 13 is covered with the light shielding film 161, the radiation detection element 11 can perform an operation of detecting a radiation while preventing the occurrence of noise which is due to light. For this reason, a window including a window plate for light shielding is not required to be provided in the opening 131. In addition, since the radiation detector 1 does not include the cooling unit and the inside of the cover 13 and the bottom plate portion 14 is not airtight, a window including a window plate for airtightness is not required to be provided in the opening 131. Therefore, the radiation detector 1 does not include the window including the window plate, and the opening 131 is not closed. Here, the expression “the opening 131 is not closed” implies that the position which faces the light shielding film 161 provided on the top surface 111 of the radiation detection element 11 is open. For example, also in the example illustrated in FIG. 6, the opening 131 is not closed. Since the radiation detector 1 does not include the window including the window plate, no radiation is transmitted through the window plate, and even a low-energy radiation is more easily incident into the radiation detection element 11. For this reason, in the radiation detector 1, a sensitivity of detecting the low-energy radiation is improved. The radiation detection device 10 facilitates the analysis of light elements radiating a low-energy radiation.

In addition, in the first embodiment, since the radiation detector 1 does not include the window including the window plate, the size of the radiation detector 1 is smaller than that in the related art. In addition, since the radiation detector 1 does not include a collimator, the size of the radiation detector 1 is smaller than that in the related art. In addition, since the cooling unit is not disposed inside the cover 13, the size of the cover 13 is smaller and the size of the radiation detector 1 is smaller than those in the related art. In addition, since the inside of the cover 13 and the bottom plate portion 14 is not airtight, the cover 13 and the bottom plate portion 14 do not require strengths and sizes to maintain an airtight state. A portion of the cover 13 except the overlapping portion 132 may be made of a resin. For this reason, it is possible to decrease the sizes of the cover 13 and the bottom plate portion 14, and the size of the radiation detector 1 is small. Since the size of the radiation detector 1 is smaller than that in the related art, in the radiation detection device 10, it is possible to dispose the radiation detector 1 closer to the sample stage 5 than in the related art. In other words, it is possible to bring the radiation detection element 11 closer to the sample 6 than in the related art. Since the radiation detection element 11 is brought close to the sample 6, the efficiency of detecting the radiation generated from the sample 6 is improved. Therefore, in the radiation detection device 10, the efficiency of detecting the radiation generated from the sample 6 is improved.

### Second Embodiment

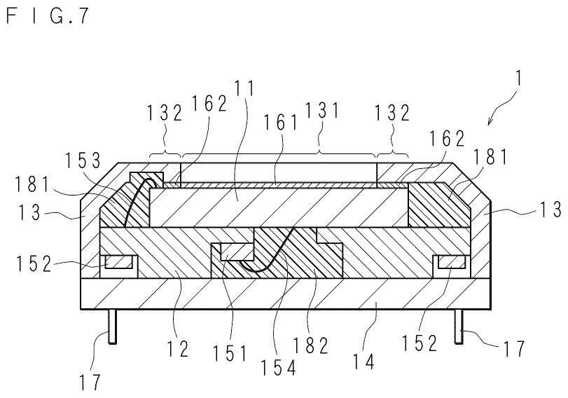

FIG. 7 is a schematic cross-sectional view illustrating an example of configuration of the radiation detector 1 according to a second embodiment. A gap between the radiation detection element 11 and the substrate 12 and the inner surface of the cover 13 is filled with a filler 181. In addition, a gap between the radiation detection element 11 and the substrate 12 and an inner surface of the bottom plate portion 14 is filled with a filler 182. The fillers 181 and 182 have insulation properties. It is desirable that the fillers 181 and 182 have light shielding properties. The materials of the filler 181 and 182 are, for example, resins. The gaps may not be completely filled with the fillers 181 and 182, and gaps which are not filled with the fillers 181 and 182 may remain. However, it is desirable that the bonding wire 153 is embedded in the filler 181, and it is desirable that the bonding wire 154 is embedded in the filler 182. The configuration of the other portion of the radiation detector 1 is the same as that in the first embodiment, and the configuration of the radiation detection element 11 is the same as that in the first embodiment. In addition, the configuration of the radiation detection device 10 except the radiation detector 1 is the same as that in the first embodiment.

It is desirable that the fillers 181 and 182 have light shielding properties. When the fillers 181 and 182 have light shielding properties, light is more effectively prevented from being incident into the radiation detection element 11, and noise due to light is more effectively prevented from occurring in the radiation detection element 11.

Since the bonding wires 153 and 154 are embedded in the fillers 181 and 182, the bonding wires 153 and 154 are protected from moisture. For this reason, the bonding wires 153 and 154 are prevented from being deteriorated by moisture. In addition, the bonding wire 153 is prevented from separating from the radiation detection element 11 or the substrate 12, and the bonding wire 154 is prevented from separating from the radiation detection element 11 or the amplifier 151.

The radiation detection element 11 and the substrate 12 are protected from moisture by the fillers 181 and 182. For this reason, the electrodes and the wiring provided in the radiation detection element 11 and the substrate 12 are prevented from being deteriorated by moisture. In addition, the radiation detection element 11 and the substrate 12 are covered with the fillers 181 and 182; and thereby, a current leakage is suppressed from occurring in the electrodes and the wiring provided in the radiation detection element 11 and the substrate 12. As described above, since the radiation detector 1 includes the fillers 181 and 182, the durability of the radiation detector 1 is improved.

### Third Embodiment

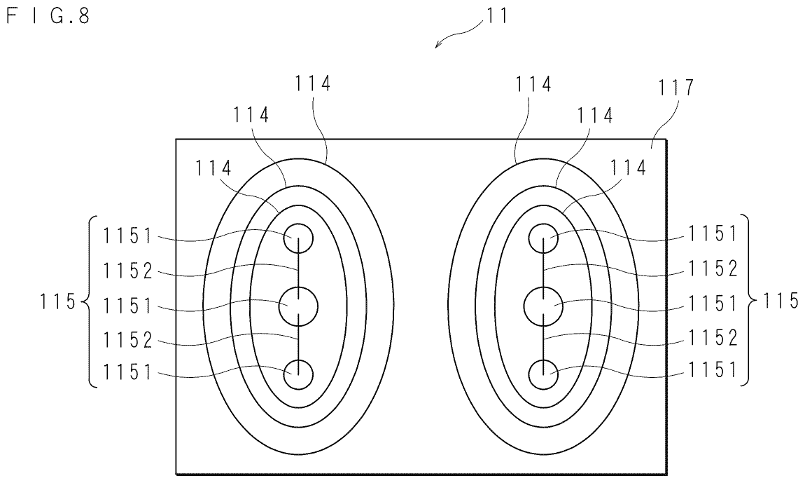

FIG. 8 is a schematic plan view of the radiation detection element 11 according to a third embodiment. FIG. 8 illustrates the radiation detection element 11 when viewed from a back surface 117 which is opposite to the top surface 111. A plurality of sets of the signal output electrodes 115 and the plurality of second electrodes 114 which surround the signal output electrode 115 in a multiplex manner are provided in a back surface 117 of the semiconductor portion 112. The second electrode 114 has a shape where the length of the second electrode 114 in one direction along the back surface 117 is longer than a length thereof in the other direction along the back surface 117. One direction where the length is longer than the length in the other direction is referred to as a longitudinal direction. For example, the shape of the second electrode 114 is an ellipse in a plan view, and the longitudinal direction is a direction along a major axis of the ellipse. A plurality of sets of the second electrodes 114 are arranged in a direction intersecting the longitudinal direction. FIG. 8 illustrates an example where two sets of the second electrodes 114 are provided. The number of sets of the multiplexed second electrodes 114 may be two or greater. FIG. 8 illustrates an example where each set includes three second electrodes 114; however, actually, a larger number of the second electrodes 114 are provided.

The signal output electrode 115 including a plurality of small electrodes 1151 is provided at a position that is surrounded by each set of the multiplexed second electrodes 114. The plurality of small electrodes 1151 are arranged along the longitudinal direction. The plurality of small electrodes 1151 are connected to each other via wires 1152. Similar to the first or second embodiment, the first electrode 113 is provided in the top surface 111, and the radiation detector 1 includes the light shielding film 161. The first electrode 113, the second electrode 114 at an innermost position, and the second electrode 114 at an outermost position are connected to the voltage application unit 34. When the voltage application unit 34 applies a voltage, an electric field where the closer to the signal output electrode 115, the higher the potential is generated inside the semiconductor portion 112. Electric charges flow into each of the small electrodes 1151. A plurality of the signal output electrodes 115 are connected to the amplifier 151. Since the plurality of small electrodes 1151 are connected to each other, the amplifier 151 may be connected to the signal output electrode 115 without being connected to each of the small electrodes 1151. Compared to when the amplifier 151 is connected to each of the small electrodes 1151, the number of the amplifiers 151 is further reduced and the number of components of the radiation detection element 11 is further reduced. The configuration of the other portion of the radiation detector 1 and the configuration of the radiation detection device 10 are the same as those in the first or second embodiment. It is noted that the radiation detector 1 may include a plurality of the amplifiers 151, and the amplifiers 151 may be one-to-one connected to the signal output electrodes 115.

In the third embodiment, since the plurality of sets of the second electrodes 114 and the signal output electrodes 115 are arranged in the direction intersecting the longitudinal direction, the radiation detection element 11 can improve the accuracy of detecting a radiation in the direction intersecting the longitudinal direction. When the signal output electrode 115 is a single electrode and the size of the signal output electrode 115 is substantially uniform in any direction along the back surface 117, a distance between the signal output electrode 115 and the second electrode 114 changes depending on the direction along the back surface 117. The electric field generated inside the semiconductor portion 112 differs depending on the direction, and the flow speed of an electric charge changes depending on the position where the electric charge is generated inside the semiconductor portion 112. For this reason, the speed of movement of electric charges toward the signal output electrode 115 varies, the time required for signal processing increases, and the time resolution of the detection of a radiation decreases. When the signal output electrode 115 has a long shape in the longitudinal direction, the distance between the signal output electrode 115 and the second electrode 114 becomes uniform; however, the area of the signal output electrode 115 increases. When the area increases, the capacity of the signal output electrode 115 increases, a signal per electric charge decreases, and the ratio of signal intensity to noise when a radiation is detected deteriorates.

In the third embodiment, since the signal output electrode 115 does not have a long shape in the longitudinal direction but the signal output electrode 115 includes the plurality of small electrodes 1151, an increase in the area of the signal output electrode 115 is suppressed. An increase in the capacity of the signal output electrode 115 is suppressed, and a deterioration in the ratio of signal intensity to noise when a radiation is detected is suppressed. In addition, since the plurality of small electrodes 1151 are arranged along the longitudinal direction, a change in the distance between the signal output electrode 115 and the second electrode 114 is small. For this reason, a variation in the speed of movement of electric charges toward the signal output electrode 115 decreases, an increase in the time required for signal processing is suppressed, and a decrease in the time resolution of the detection of a radiation is suppressed. It is noted that the radiation detection element 11 may include the second electrode 114 that individually surrounds the small electrode 1151. For example, the second electrode 114 may individually surround each of the small electrodes 1151, the plurality of small electrodes 1151 may be connected to each other via the wires 1152, and another second electrode 114 may surround a plurality of sets of the small electrode 1151 and the second electrode 114 which surrounds the small electrode 1151.

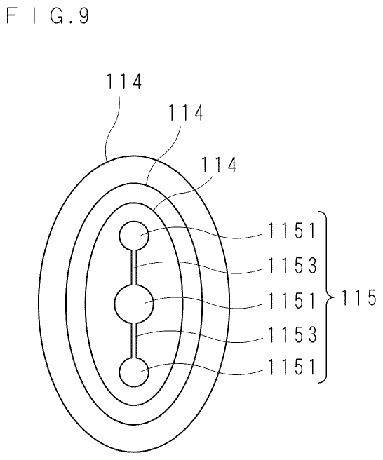

FIG. 9 is a schematic plan view illustrating a second example of configuration of the signal output electrode 115 in the third embodiment. The signal output electrode 115 includes the plurality of small electrodes 1151. The plurality of small electrodes 1151 are arranged along the longitudinal direction. The plurality of small electrodes 1151 are connected to each other via a line electrode 1153 provided in the back surface 117. The line electrode 1153 is an electrode having a line shape, and is formed of the same component as that of the small electrode 1151. Electric charges flow also into the line electrode 1153. Also in this configuration, an increase in the area of the signal output electrode 115 is suppressed. In addition, a change in the distance between the signal output electrode 115 and the second electrode 114 is small, and a variation in the speed of movement of electric charges toward the signal output electrode 115 is small.

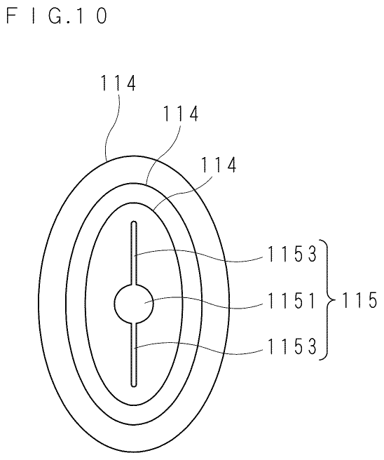

FIG. 10 is a schematic plan view illustrating a third example of configuration of the signal output electrode 115 in the third embodiment. The signal output electrode 115 includes a single small electrode 1151 and the line electrode 1153 provided in the back surface 117. The line electrode 1153 is connected to the small electrode 1151 and extends along the longitudinal direction. Also in this configuration, an increase in the area of the signal output electrode 115 is suppressed. In addition, since the line electrode 1153 extends along the longitudinal direction, a portion of the second electrode 114 which is far from the small electrode 1151 is closer to the line electrode 1153. For this reason, a change in the distance between the signal output electrode 115 and the second electrode 114 is small, and a variation in the speed of movement of electric charges toward the signal output electrode 115 is small.

The third embodiment discloses the configuration where the radiation detection element 11 includes the plurality of sets of the signal output electrodes 115 and the multiplexed second electrodes 114. However, the radiation detection element 11 may be configured to include only one set of the signal output electrode 115 and the multiplexed second electrodes 114 of which each has a shape where the length thereof in one direction is longer than the length thereof in the other direction. In addition, the radiation detector 1 according to the third embodiment can have a form where the opening 131 is closed by a window plate. The radiation detector 1 in which the opening 131 is closed by the window plate may not include the light shielding film 161 or the bonding member 162 having light shielding properties.

### Fourth Embodiment

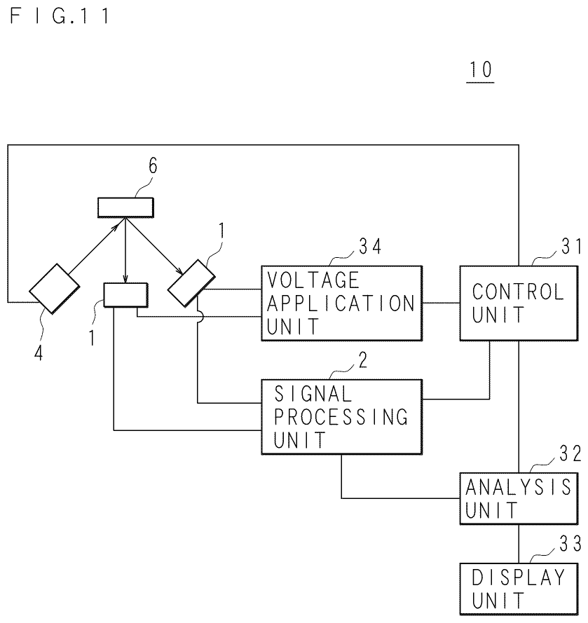

FIG. 11 is a block diagram illustrating the configuration of the radiation detection device 10 according to a fourth embodiment. The radiation detection device 10 according to the fourth embodiment includes a plurality of the radiation detectors 1. The irradiation unit 4 irradiates the sample 6 with a radiation, and a radiation generated from the sample 6 is detected by the plurality of radiation detectors 1. In the drawing, the radiation is indicated by the arrows. Each of the plurality of radiation detectors 1 is connected to the voltage application unit 34 and the signal processing unit 2. The voltage application unit 34 applies a voltage to the radiation detection element 11 inside each of the radiation detectors 1. The signal processing unit 2 processes signals output from the plurality of radiation detectors 1. The analysis unit 32 performs various analyses based on detection results of the plurality of radiation detectors 1. It is noted that the radiation detection device 10 may include a plurality of the voltage application units 34 and the signal processing units 2, and one radiation detector 1 may be connected to one voltage application unit 34 and one signal processing unit 2.

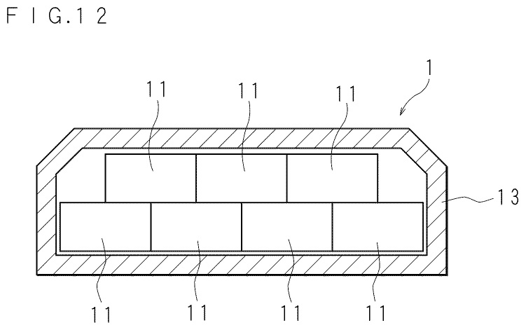

FIG. 12 is a schematic view illustrating an example of configuration of the inside of the radiation detector 1 according to the fourth embodiment. FIG. 12 illustrates the disposition of the radiation detection elements 11 inside the radiation detector 1 in a plan view. The radiation detector 1 includes a plurality of the radiation detection elements 11. The plurality of radiation detection elements 11 are disposed inside the cover 13 with the top surfaces 111 facing the same direction. For example, as illustrated in FIG. 12, the plurality of radiation detection elements 11 are arranged in two rows. FIG. 12 illustrates an example where seven radiation detection elements 11 are disposed inside the radiation detector 1; however, the number of the radiation detection elements 11 inside the radiation detector 1 may be a number other than seven. The plurality of radiation detection elements 11 may be integrally formed, or may be individually separated from each other. The configuration of each of the radiation detection elements 11 is the same as that in any one of the first to third embodiments. The radiation detector 1 includes a plurality of amplifiers 151, and the signal output electrodes 115 in the radiation detection element 11 are connected to the amplifiers 151. It is noted that the radiation detector 1 may include a smaller number of the amplifiers 151 than the number of the radiation detection elements 11, and a plurality of the signal output electrodes 115 may be connected to one amplifier 151. The configuration of the other portion of the radiation detector 1 is the same as that in the first to third embodiments. In addition, the configuration of the other portion of the radiation detection device 10 is the same as that in the first to third embodiments.

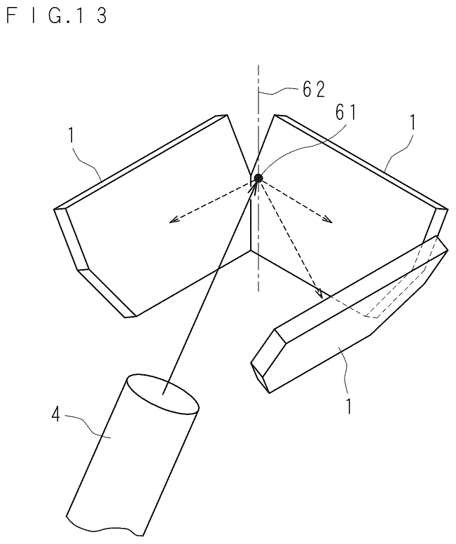

FIG. 13 is a schematic perspective view illustrating an example of the disposition of the plurality of radiation detectors 1 according to the fourth embodiment. A radiation such as an X-ray with which the sample 6 is irradiated by the irradiation unit 4 is indicated by the solid arrow. Reference numeral 61 in the drawing denotes an irradiation position on the sample 6 when irradiated with a radiation from the irradiation unit 4. A straight line 62 which passes through the irradiation position 61 and intersects the sample 6 is indicated by the alternate long and short dash line. For example, the straight line 62 is orthogonal to a surface of the sample 6. The plurality of radiation detectors 1 are disposed at positions surrounding the straight line 62. The plurality of radiation detectors 1 are disposed such that front surfaces thereof face the irradiation position 61. For this reason, the top surface 111 of each of the radiation detection element 11 faces the irradiation position 61. When the sample 6 is irradiated with a radiation, a radiation such as a fluorescent X-ray is generated from the sample 6. The radiation is radially generated from the irradiation position 61, and is incident into each of the radiation detectors 1. In each of the radiation detectors 1, the radiation is incident into the radiation detection element 11, so that the radiation is detected. FIG. 13 illustrates three radiation detectors 1; however, the number of the radiation detectors 1 which are disposed may be two or four or greater.

Since the plurality of radiation detectors 1 are disposed to surround the straight line 62 and the plurality of radiation detection elements 11 are disposed inside the radiation detectors 1, the radiation is detected by a large number of the radiation detection elements 11. The X-ray generated from the sample 6 is incident into and detected by any one of the radiation detection elements 11 with a high probability. For this reason, in the radiation detection device 10 according to the fourth embodiment, the efficiency of detecting the radiation generated from the sample 6 is high. Since the efficiency of detecting the radiation is high, the radiation detection device 10 can reduce the time required to detect the radiation generated from the sample 6.

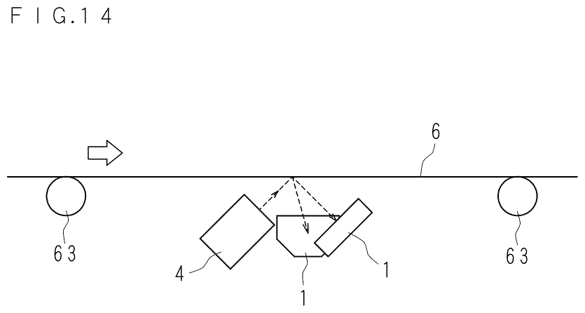

FIG. 14 is a schematic view illustrating an example of the disposition of the irradiation unit 4, the radiation detectors 1, and the sample 6 according to the fourth embodiment. The sample 6 is a long sheet, and is moved by rollers 63 in a direction indicated by the white arrow. The irradiation unit 4 and the plurality of radiation detectors 1 are disposed below the sample 6. FIG. 14 illustrates two radiation detectors 1; however, the number of the radiation detectors 1 which are disposed may be three or greater. It is noted that the irradiation unit 4 and the radiation detectors 1 may be disposed in a divided manner on one side and the other side of the sample 6.

The sample 6 is continuously moved, and the irradiation unit 4 continuously irradiates the sample 6 with a radiation. When the sample 6 is moved, a plurality of portions on the sample 6 are sequentially irradiated with the radiation, and a radiation is sequentially generated from the portions. The plurality of radiation detectors 1 sequentially detect the radiation generated from the sample 6, and the analysis unit 32 sequentially performs analyses. In FIG. 14, the radiation is indicated by the dashed line arrows. For example, the radiation detectors 1 detect the fluorescent X-ray generated from the sample 6, and the analysis unit 32 measures the amount of impurities contained in the sample 6. The analysis unit 32 measures the thickness of the sample 6 from the intensity of the detected fluorescent X-ray, for example, by using that the intensity of a fluorescent X-ray from a base material of the sample 6 changes depending on the thickness of the sample 6.

For example, the sample 6 is an industrial product, and when the amount of impurities or the thickness of the sample 6 is measured using the radiation detection device 10 and the amount of impurities or the thickness of the sample 6 is out of an allowable range, it is possible to determine that the sample 6 has an abnormality. In the radiation detection device 10, since the time required to detect the radiation generated from the sample 6 is short, the time required to determine the abnormality of the sample 6 is also short. For this reason, it is possible to shorten the movement time of the sample 6 when the abnormality of the sample 6 is determined. Therefore, it is possible to execute the production and inspection of the sample 6 efficiently in time by using the radiation detection device 10 according to the fourth embodiment.

It is noted that the radiation detector 1 according to the fourth embodiment can have the form where the opening 131 is closed by a window plate. The radiation detector 1 in which the opening 131 is closed by the window plate may not include the light shielding film 161 or the bonding member 162 having light shielding properties.

It is noted that, in the first to fourth embodiments described above, the form where the radiation detector 1 does not include the cooling unit such as a Peltier element is adopted. However, the radiation detector 1 may include a temperature control unit that keeps the temperature of the radiation detection element 11 constant. The Peltier element may be used as the temperature control unit; however, the cooling capacity of the temperature control unit may be lower than that of a cooling unit in the related art, a temperature difference between inside and outside of the cover 13 and the bottom plate portion 14 is within 10° C., and the cooling is not performed to a temperature where condensation occurs. Since the cooling capacity of the temperature control unit may be low, the temperature control unit is smaller than the cooling unit in the related art. For this reason, even when the radiation detector 1 is configured to include the temperature control unit, the size of the radiation detector 1 is smaller than that in the related art. In addition, in the first to fourth embodiments, the form where the radiation detection element 11 is a silicon drift detection element is adopted; however, as long as the radiation detection element 11 is a semiconductor element, the radiation detection element 11 may be an element other than the silicon drift detection element. For this reason, the radiation detector 1 may be a radiation detector other than a silicon drift detector. For example, the radiation detector 1 may be a pixel array semiconductor detector for detecting X-ray energy.

In addition, in the first to fourth embodiments, the form where the sample 6 is irradiated with the radiation and the radiation generated from the sample 6 is detected is adopted. However, the radiation detection device 10 may be configured to detect a radiation that is transmitted through the sample 6 or is reflected by the sample 6. In addition, the radiation detection device 10 may be configured to scan the sample 6 with a radiation by changing the direction of the radiation. In addition, the radiation detection device 10 may be configured to not include the irradiation unit 4, the sample stage 5, the analysis unit 32, or the display unit 33. Even when the radiation detection device 10 is configured to not include the irradiation unit 4 and the sample stage 5, the radiation detection device 10 can be used such that the radiation detection element 11 is brought closer to the sample than in the related art; and thereby, the efficiency of detecting the radiation can be improved.

The present invention is not limited to the contents of the above-described embodiments, and various changes can be made without departing from the scope of the claims. Therefore, an embodiment which is obtained by combining technical means appropriately changed within the scope of the claims is also included in the technical scope of the present invention.

It is to be noted that, as used herein and in the appended claims, the singular forms “a”, “an”, and “the” include plural referents unless the context clearly dictates otherwise.

It is to be noted that the disclosed embodiment is illustrative and not restrictive in all aspects. The scope of the present invention is defined by the appended claims rather than by the description preceding them, and all changes that fall within metes and bounds of the claims, or equivalence of such metes and bounds thereof are therefore intended to be embraced by the claims.

What is claimed is:

1. A silicon drift detector, comprising:
a housing; and
the silicon drift detection element being disposed inside the housing; and
a light shielding film,
wherein the housing includes an opening that is not closed,
the silicon drift detection element includes:
a top surface facing the opening;
a signal output electrode which is provided in a back surface of the silicon drift detection element opposite to the top surface, into which an amount of electric charges generated by an incidence of the radiation according to the energy of the radiation flows, and which outputs a signal depending on the electric charges;
a first electrode which is provided in the top surface and to which a voltage is applied; and
a plurality of second electrodes that are provided in the back surface to surround the signal output electrode, and are positioned at different distances from the signal output electrode, and
the light shielding film is provided on the top surface.

2. The silicon drift detector according to claim 1, wherein
the top surface includes a first portion where radiation is incident and another portion where radiation is not incident, and
the light shielding film covers the first portion and does not cover the another portion.

3. The silicon drift detector according to claim 1, wherein
the top surface is larger than the opening,
the housing includes an overlapping portion that includes an edge of the opening and overlaps a part of the top surface, and
a portion in the top surface, which is surrounded by another portion overlapped with the overlapping portion, is covered with the light shielding film.

4. The silicon drift detector according to claim 1, wherein
the silicon drift detector does not include a cooling unit that cools the silicon drift detection element, and
the housing is not airtight.

5. The silicon drift detector according to claim 1, wherein
a window plate is not provided at a position facing the top surface.

6. The silicon drift detector according to claim 1, further comprising
a filler with which a gap between the housing and the silicon drift detection element is filled.

7. The silicon drift detector according to claim 1, wherein
the light shielding film reduces an amount of light incident into the top surface to less than 0.1%.

8. The silicon drift detector according to claim 1, wherein
the light shielding film is a metallic film with a thickness exceeding 50 nm but less than 500 nm.

9. The silicon drift detector according to claim 1, wherein
the light shielding film is a carbon film.

10. A radiation detection device, comprising:
the silicon drift detector according to claim 1; and
a spectrum generation unit that generates a spectrum of a radiation detected by the silicon drift detector.

11. A radiation detection device, comprising:
an irradiation unit that irradiates a sample with a radiation;
the silicon drift detector according to claim 1 which detects a radiation generated from the sample;
a spectrum generation unit that generates a spectrum of the radiation detected by the silicon drift detector; and
a display unit that displays the spectrum generated by the spectrum generation unit.
